(19) United States
(12) Patent Application Publication
(10) Pub. No.: US 2020/0088772 A1
(43) Pub. Date: Mar. 19, 2020

(54) SYSTEMS AND METHODS TO MEASURE PRIMARY VOLTAGE USING CAPACITIVE COUPLED TEST POINT AND GROUNDED SENSOR CIRCUIT

(71) Applicant: SENTIENT ENERGY, INC., Burlingame, CA (US)

(72) Inventor: Ronald S. RUMRILL, Union City, CA (US)

(21) Appl. No.: 16/574,465

(22) Filed: Sep. 18, 2019

Related U.S. Application Data
(60) Provisional application No. 62/732,770, filed on Sep. 18, 2018.

(51) Int. Cl. G01R 19/25

(52) U.S. Cl. CPC G01R 19/2513

(57) ABSTRACT

A voltage measuring system is provided that can include a number of features. The system can include a sensing device configured to measure a true primary voltage of a high-voltage conductor. In some examples, the sensing device can be configured to electrically connect to a voltage test point of a loadbreak connector. The sensing device can include a current-to-voltage converter circuit and an integrator circuit to provide an output representative of the true primary voltage of the high-voltage conductor. Methods of using the sensing devices are also provided.

### CROSS REFERENCE TO RELATED APPLICATIONS

This application claims the benefit of U.S. Provisional Patent Application No. 62/732,770, filed Sep. 18, 2018, titled “Systems and Methods to Measure Primary Voltage Using Capacitive Coupled Test Point and Grounded Sensor Circuit”, the contents of which are incorporated by reference herein.

### INCORPORATION BY REFERENCE

All publications and patent applications mentioned in this specification are herein incorporated by reference to the same extent as if each individual publication or patent application was specifically and individually indicated to be incorporated by reference.

### FIELD

The present application relates generally to distribution line monitoring and sensor monitoring.

### BACKGROUND

Voltage measurements on power distribution networks typically require a connection to high voltage conductors. This is often problematic, in that the voltages demand substantial standoff distances and other precautions due to the high, dangerous voltages. The common industry practice is to reduce this voltage to a lower (and therefore safer) voltage before applying it to monitoring equipment. This is typically accomplished by resistive or capacitive dividers or by step-down transformers.

Underground electrical systems are particularly difficult to connect to the high voltage conductors for voltage measurements because they are often part of an insulated cable assembly. Maintaining the integrity of the insulation does not allow for conventional types of connections. The industry has developed connectors for use in underground electrical systems that incorporate a capacitively-coupled voltage tap, sometime called a voltage test point.

Industry standards dictate that the voltage test point must have one picofarad of capacitance to the high voltage conductor. The amount of capacitance is directly proportional to the physical separation of the capacitor electrodes and the area of those electrodes. The voltage withstanding requirement of these test points demands a certain separation and the practical size of the test point suggests a reasonable area.

There is a need to be able to measure voltage on power distribution networks with a voltage test point that is immune to parasitic effects and does not require an ultra-high impedance circuit.

### SUMMARY OF THE DISCLOSURE

A sensing device configured to measure a voltage on a power distribution conductor that is connected to a loadbreak connector is provided, comprising a housing configured to electrically connect to a voltage test point of the loadbreak connector, wherein the voltage test point includes a predetermined capacitance, a current-to-voltage converter circuit disposed in the housing and configured to produce an output voltage when the housing is electrically connected to the voltage test point, and an integrator circuit electrically disposed in the housing and electrically connected to the current-to-voltage converter circuit, the integrator circuit being configured to receive the output voltage from the current-to-voltage converter circuit as an input, the integrator circuit being further configured to produce an integrated output signal that represents a true primary voltage of the power distribution conductor.

In one embodiment, the predetermined capacitance comprises approximately 1 picofarad or less.

In some examples, electrically connecting the housing to the voltage test point grounds the voltage test point.

A method of sensing a voltage of a power distribution conductor is also provided, comprising the steps of inputting a voltage test point current of the power distribution conductor into a current-to-voltage converter circuit of a sensing device to produce an output voltage representing the voltage test point current, inputting the output voltage into an integrator circuit of the sensing device to produce an integrated output voltage that represents a true primary voltage of the power distribution conductor, and outputting the integrated output voltage from the sensing device.

In one example, prior to the inputting steps, the method can further include electrically connecting the sensing device to a loadbreak connector of the power distribution conductor.

In some embodiments, the voltage test point current comprises a current flowing through a capacitor of a voltage test point of the loadbreak connector.

In one embodiment, the capacitor has a capacitance of approximately 1 picofarad or less.

In some examples, the method can further comprise grounding the voltage test point.

A voltage measurement system is also provided, comprising a power distribution conductor, a loadbreak connector electrically connected to the power distribution conductor, the loadbreak connector including a voltage test point that comprises a capacitor, and a sensing device configured to electrically connect to the voltage test point of the loadbreak connector, the sensing device including a current-to-voltage converter circuit configured to produce an output voltage when the sensing device is electrically connected to the voltage test point and an integrator circuit electrically connected to the current-to-voltage converter circuit, the integrator circuit being configured to receive the output voltage from the current-to-voltage converter circuit as an input, the integrator circuit being further configured to produce an integrated output signal that represents a true primary voltage of the power distribution conductor.

### BRIEF DESCRIPTION OF THE DRAWINGS

The novel features of the invention are set forth with particularity in the claims that follow. A better understanding of the features and advantages of the present invention will be obtained by reference to the following detailed description that sets forth illustrative embodiments, in which the principles of the invention are utilized, and the accompanying drawings of which:

FIGS. 1A and 1B show one example of a connector for measuring voltage in a power distribution network.

FIG. 2 is a schematic representation of a circuit in a typical voltage test point that disadvantageously contains parasitic elements.

FIG. 3A shows a current to voltage converter circuit of a sensing device that is configured to accurately measure voltage in a power distribution network.

FIG. 3B is a schematic drawing showing a integrator circuit of a sensing device that is configured to accurately measure voltage in a power distribution network.

FIG. 4A illustrates a connector for measuring voltage in a power distribution network with a cap removed to expose a voltage test point.

FIGS. 4B-4C illustrate one embodiment of a sensing device that is configured to be attached to the connector of FIG. 4A at the voltage test point to provide a true representation of the voltage of the high-voltage conductor.

FIG. 5 is a flowchart that describes a method for accurately measuring the voltage of a high-voltage conductor.

### DETAILED DESCRIPTION

Power line monitoring devices and systems described herein are configured to measure the voltages of power grid distribution networks, particularly of difficult to measure underground power distribution networks.

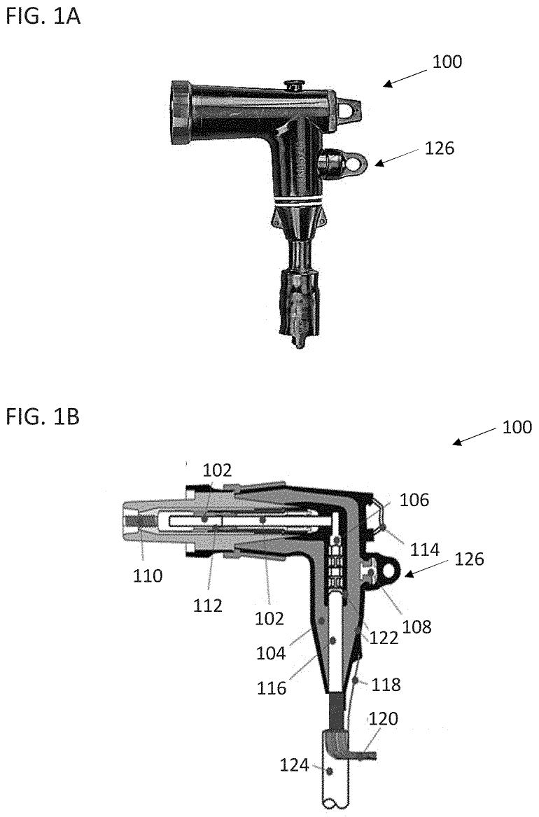

FIGS. 1A and 1B illustrate one example of a connector 100 for measuring voltage in an underground electrical system. This connector, sometimes referred to as an elbow connector or loadbreak connector, is a fully-shielded and insulated plug-in termination for connecting underground cable to transformers, switching cabinets, and junctions equipped with loadbreak bushings. The connector 100 is configured to attach to a high-voltage conductor, such as a high voltage underground electrical system. In the cross-sectional view of FIG. 1A, the connector 100 can include a loadbreak probe 102 and probe tip 103 within an insulative housing 104. A compression connector 106 can be electrically coupled to the loadbreak probe 102. A test point 108 provides an access point to test the voltage of the lines connected to the connector 100. Among other features, the connector 100 can include a bushing stud 110, tulip contacts between the probe tip 103 and the loadbreak probe 102, a pulling eye 114, cable insulation 116, ground wire(s) 118, cable shield wires 120, a semi-conductive layer 122, and a polymer insulated cable 124. As shown in FIG. 1A, the semi-conductive layer 122 is disposed within the insulative housing, surrounding the loadbreak probe 102 and compression connector 106, and is also disposed outside of the insulative housing. Since the loadbreak probe 102 and compression connector 106 are electrically connected to a high-voltage conductor, the arrangement of the insulative housing and two layers of the semi-conductive layer 122 have the effect of forming capacitive voltage tap (e.g., one picofarad capacitance) at the test point 108. A cap 126 can be placed over the test point 108 and serves to ground the test point 108 via ground wire(s) 118 when the cap is in place.

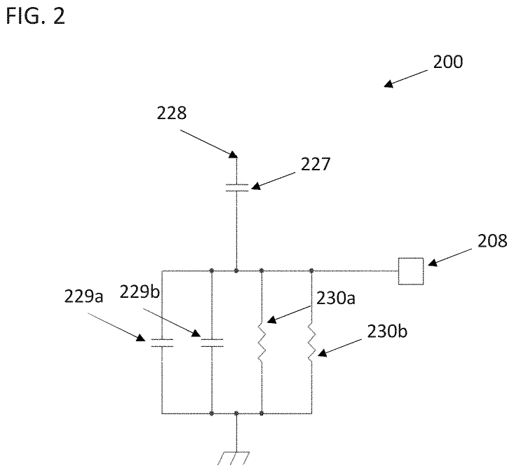

From a signal monitoring point of view, the connector 100 that is typically used in the art has several disadvantages, beginning with limiting the voltage test point to one picofarad. With a high voltage connected to one side of this one picofarad capacitance, any circuit placed on the other side of the capacitance (i.e., the monitoring electrode of the test point 108) will form a “divider” circuit. FIG. 2 illustrates a representative “divider” circuit 200 for a conventional voltage test point 208 with a one picofarad capacitance, represented by capacitor 227, electrically connected to a high-voltage conductor 228. The voltage measured on the test point 208 is the mid-point of this divider circuit; one side of the divider being the high voltage conductor, and the other side being whatever circuitry connects to the test point, typically the sensing devices that are attached to the test point to test the voltage of the conductor. In the illustrated example, this circuitry is the composite load on the test point which can contain both desired and parasitic elements, represented by capacitors 229a and 229b and resistors 230a and 230b. As with any divider circuit, the mid-point signal is determined by the ratio of the two halves of the divider. In this example, due to the small one picofarad capacitance of capacitor 227, the midpoint (i.e., the test voltage) will be easily influenced by small amounts of capacitance or resistance in the divider's “lower” half. Because the test point electrode is the mid-point of the divider, the entirety of the measurement device being connected to the test point becomes the entire lower half of the divider. This includes the purposeful designed parts of the circuitry as well as the unintentional parasitic parts of the circuitry. In the common vernacular, the source is electrically “weak, and therefore accurate measurement of this voltage must be performed with an ultra-high impedance circuit, included only in specialized measurement tools, as to not unduly load the test point.

This disclosure provides a novel sensing device that connects to an existing voltage test point for accurately and safely measuring voltage on high voltage conductors without the disadvantages normally found in voltage test points (i.e., parasitic effects, requirement for ultra-high impedance circuits, etc.). The present disclosure provides a test point circuit that measures the current delivered through a capacitor of a voltage test point when the test point is at a near ground potential. This disclosure further provides a sensing device that can be attached to a conventional elbow connector to sense the voltage on the high voltage conductors.

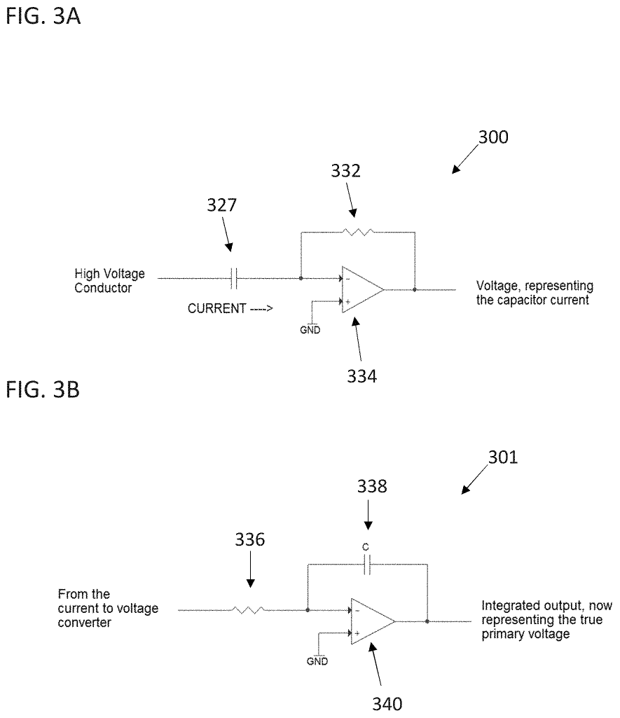

The sensing device provided herein includes a test point circuit that includes two main components. The first component is a current to voltage converter that takes, as an input, the current from the high-voltage conductor flowing through the internal capacitor of a loadbreak connector as described above. This current to voltage converter provides an output voltage that represents the capacitor current of the capacitive voltage test point of the loadbreak connector. FIG. 3A is a schematic drawing of a current to voltage converter 300 that can be integrated into a test point circuit and sensing device, as discussed herein. The current to voltage converter 300 receives, as an input, current flowing from the high-voltage conductor through the internal capacitor 327 (corresponding to capacitor 227 of FIG. 2) of the loadbreak connector (e.g., the one picofarad capacitor). This current is then applied to the current-to-voltage converter which comprises a resistor 332 and an opamp 334 as shown. The current through a capacitor depends on the capacitive reactance, which is given by the equation

$${X}_{c} = \frac{1}{2 π fc}$$

Solving this equation for 60 Hz and one picofarad yields a capacitive reactance of more than 2 gigaohms. With a typical distribution voltage of 12 kV to 25 kV, this will deliver 4-6 micromps of current into the input of the current-to-voltage converter.

The output of the current-to-voltage converter 300, because it represents a capacitive current, has a rising frequency response (20 dB per decade), and a 90° phase lead. The output of the current-to-voltage converter is a voltage representing the current through capacitor 327, as shown.

Next, referring to FIG. 3B, the test point circuit can further include an integrator 301 that receives, as an input, the output voltage from the current-to-voltage converter of FIG. 3A. The integrator 301 can include a resistor 336, a capacitor 338, and an opamp 340. The integrator 301 can have a falling frequency response (−20 dB per decade) and 90° phase lag. Applying the current from the current-to-voltage converter 300 to the integrator 301 results in an output signal that is restored to a true representation of the primary voltage on the high voltage conductor.

One key advantage of the test point being near ground potential is that it becomes almost immune to the parasitic effects that affect a voltage measurement of the same test point. If a voltage existed on the test point, even small amounts of surface contamination would draw certain amounts of currents, creating an error. With near zero voltage on the test point, there is no potential to drive any current through the contamination. The current flowing through capacitor is driven by the high, primary voltage, and thus can be considered a nearly ideal current source.

Another advantage of the present approach is that there is no concern that a relative high voltage could appear at a test point during a measurement. With the test point at near ground potential the risk equipment damage and personnel safety is enhanced. The small output current of 4-6 microamps is well below even the human perception level.

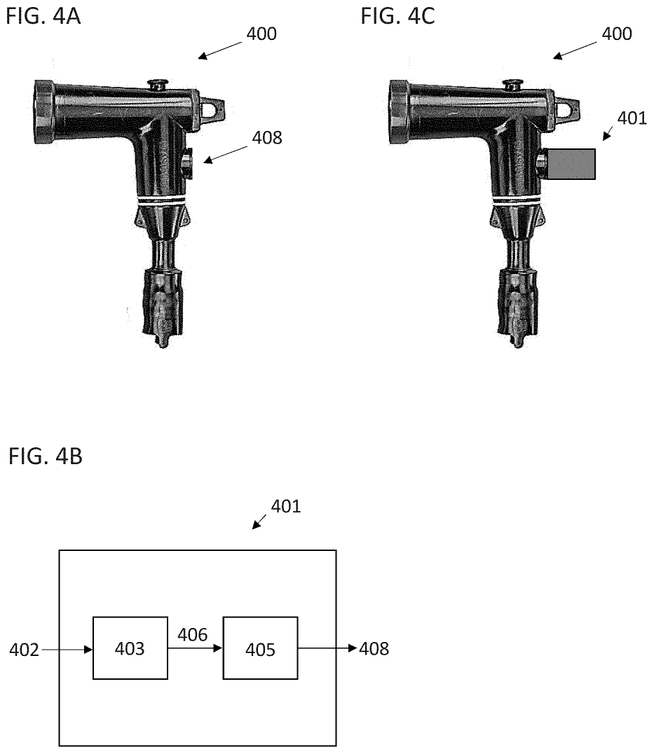

FIG. 4A illustrates a connector 400, identical to the connector 100 of FIGS. 1A-1B, except the cap 126 of connector 100 has been removed to expose test point 408. FIG. 4B is a schematic diagram of a testing device 401 that includes the test point circuit described above. The test point circuit comprises a current-to-voltage converter circuit 403 and an integrator circuit 405, as shown. As described above, the input to the current-to-voltage converter circuit 403 is the current flowing from the high-voltage conductor through the voltage test point capacitor of connector 400. Current-to-voltage converter circuit 403 produces an output 406, which is a voltage that represents the current through the capacitor of the voltage test point. This output is then inputted into the integrator circuit 405, which produces an output that is a true representation of the primary voltage on the high-voltage conductor.

FIG. 4C illustrates a sensing device 401 of the present disclosure attached to the connector 400 at the voltage test point. As described above, the sensing device can be configured to produce an output voltage that is a true representation of the primary voltage on the high-voltage conductor. It should be noted that when the sensing device 401 is connected to the connector 400, the voltage test point is grounded in the same manner as the cap 12 in FIG. 1B grounds the test point via ground wire(s) 118.

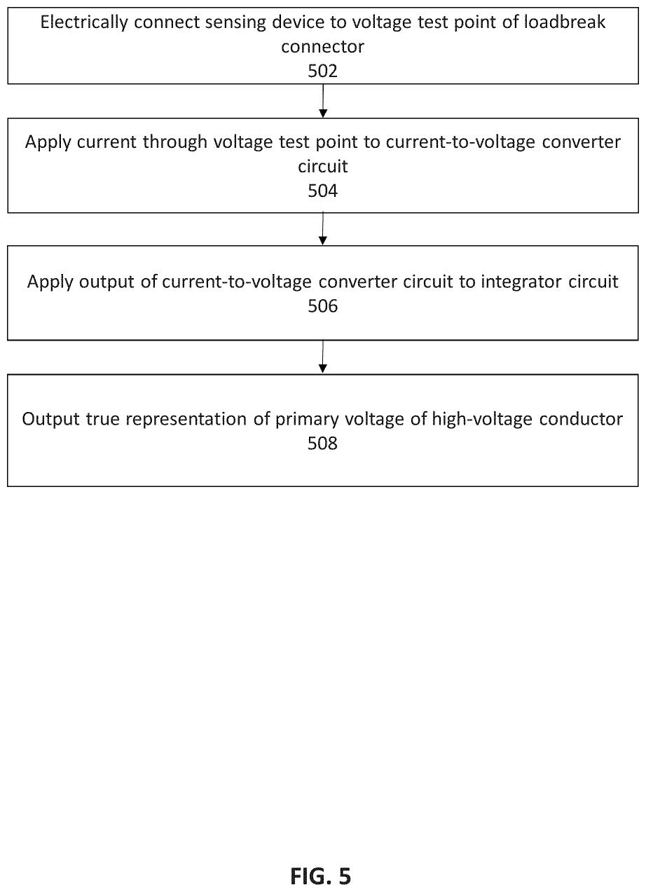

FIG. 5 is a flowchart describing the processes discussed above. At an operation 502, the method can include electrically connecting a sensing device to a voltage test point of a loadbreak connector. As described above, a voltage test point of a conventional loadbreak connector is typically covered with a cap that grounds the test point when not in use. In some examples, electrically connecting the sensing device can comprise attaching the sensing device to the voltage test point. Furthermore, connecting the sensing device can include grounding the voltage test point.

At an operation 504, the method can further include applying a current from the voltage test point to a current-to-voltage converter circuit of the sensing device. As described above, this current-to-voltage converter circuit is schematically represented by the circuit of FIG. 3A. The output of this operation comprises a voltage that represents the capacitor current of the voltage test point.

At an operation 506, the method can further include applying the output of the current-to-voltage converter circuit to an integrator circuit. The integrator circuit is configured to adjust the phase and frequency response of the input signal to produce an output signal that is a true representation of the primary voltage of the high-voltage conductor. This true representation of the primary voltage of the high-voltage conductor can be output at step 508 of the method.

As for additional details pertinent to the present invention, materials and manufacturing techniques may be employed as within the level of those with skill in the relevant art. The same may hold true with respect to method-based aspects of the invention in terms of additional acts commonly or logically employed. Also, it is contemplated that any optional feature of the inventive variations described may be set forth and claimed independently, or in combination with any one or more of the features described herein. Likewise, reference to a singular item, includes the possibility that there are plural of the same items present. More specifically, as used herein and in the appended claims, the singular forms “a,” “and,” “said,” and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Unless defined otherwise herein, all technical and scientific terms used herein have the same meaning as commonly understood by one of ordinary skill in the art to which this invention belongs. The breadth of the present invention is not to be limited by the subject specification, but rather only by the plain meaning of the claim terms employed.

What is claimed is:

1. A sensing device configured to measure a voltage on a power distribution conductor that is connected to a loadbreak connector, comprising:
a housing configured to electrically connect to a voltage test point of the loadbreak connector, wherein the voltage test point includes a predetermined capacitance;
a current-to-voltage converter circuit disposed in the housing and configured to produce an output voltage when the housing is electrically connected to the voltage test point; and
an integrator circuit electrically disposed in the housing and electrically connected to the current-to-voltage converter circuit, the integrator circuit being configured to receive the output voltage from the current-to-voltage converter circuit as an input, the integrator circuit being further configured to produce an integrated output signal that represents a true primary voltage of the power distribution conductor.

2. The sensing device of claim 1, wherein the predetermined capacitance comprises approximately 1 picofarad or less.

3. The sensing device of claim 1, wherein electrically connecting the housing to the voltage test point grounds the voltage test point.

4. A method of sensing a voltage of a power distribution conductor, comprising the steps of:
inputting a voltage test point current of the power distribution conductor into a current-to-voltage converter circuit of a sensing device to produce an output voltage representing the voltage test point current;
inputting the output voltage into an integrator circuit of the sensing device to produce an integrated output voltage that represents a true primary voltage of the power distribution conductor; and
outputting the integrated output voltage from the sensing device.

5. The method of claim 4, further comprising, prior to the inputting steps, electrically connecting the sensing device to a loadbreak connector of the power distribution conductor.

6. The method of claim 5, wherein the voltage test point current comprises a current flowing through a capacitor of a voltage test point of the loadbreak connector.

7. The method of claim 6, wherein the capacitor has a capacitance of approximately 1 picofarad or less.

8. The method of claim 5, further comprising grounding the voltage test point.

9. A voltage measurement system, comprising:
a power distribution conductor;
a loadbreak connector electrically connected to the power distribution conductor, the loadbreak connector including a voltage test point that comprises a capacitor; and
a sensing device configured to electrically connect to the voltage test point of the loadbreak connector, the sensing device including:
a current-to-voltage converter circuit configured to produce an output voltage when the sensing device is electrically connected to the voltage test point;
an integrator circuit electrically connected to the current-to-voltage converter circuit, the integrator circuit being configured to receive the output voltage from the current-to-voltage converter circuit as an input, the integrator circuit being further configured to produce an integrated output signal that represents a true primary voltage of the power distribution conductor.
